(19) United States
(12) Patent Application Publication
(10) Pub. No.: US 2007/0274893 A1
(43) Pub. Date: Nov. 29, 2007

(54) Microwave Plasma Apparatus

(75) Inventors: Neil Philip Wright, Wirral (GB); Xiaoming Duan, Essex (GB); Ba Duong Phan, Westminster, CA (US)

Correspondence Address: HAYNES AND BOONE, LLP, 901 MAIN STREET, SUITE 3100, DALLAS, TX, 75202, US

(73) Assignee: C-Tech Innovation Limited, Chester (GB)

(21) Appl. No.: 11/664,667

(22) PCT Filed: Oct. 3, 2005
(86) PCT No.: PCT/GB05/03811

§ 371 Date: Apr. 4, 2007

(30) Foreign Application Priority Data
Oct. 4, 2004 (GB) 0421998.6

(51) Int. Cl. H05H 1/30; H01J 37/32

(52) U.S. Cl. 423/449.1; 204/164; 422/186.04

(57) ABSTRACT

A microwave plasma generating apparatus (10) has a microwave cavity (20) coupled to a microwave source (22) by a wave guide (24). Within the cavity (20) is a reaction tube (30) defining a plasma cavity (40). A gas inlet manifold (50) is provided at the top of the reaction tube (30), which is formed so as to introduce plasma gas tangentially to the longitudinal axis of the plasma. Plasma gas is thus injected into the reaction tube (30) so that it flows in a swirled manner, that is, in the form of a vortex. This prevents overheating of the reaction tube (30).

### CROSS REFERENCE

This application was originally filed as Patent Cooperation Treaty Application Number PCT/GB2005/003811 filed Oct. 3, 2005, which claims priority of Great Britain Patent Application Number 0421998.6, filed Oct. 4, 2004.

### TECHNICAL FIELD

The present invention relates to a method of and apparatus for producing a microwave plasma jet, particularly but not exclusively at atmospheric pressure.

### BACKGROUND

Microwave generated plasmas are used in a wide range of different applications. A first type of plasma generator is used as a so-called API (atmospheric pressure ioniser) source in which sample material is injected in ionised form into a mass spectrometer, for spectroscopic analysis. This type of generator employs relatively sophisticated equipment with a small microwave chamber acting as a monomodal microwave cavity, adapted to very low levels of sample material. The dimensions and microwave energy mean that maintaining a plasma is relatively straightforward, although degradation may occur over time.

A separate branch of microwave plasma technology addresses such applications as the synthesis of new materials, waste gas processing and materials surface engineering. Such microwave plasma apparatuses typically have a large volume chamber adapted to accept high volumes of plasma gas for essentially industrial scale processing. For example, U.S. Pat. No. 5,782,085 discloses a microwave plasma apparatus for removing nitrogen oxides from internal combustion engine exhaust gases.

WO 96/02934 shows a microwave plasma apparatus of the latter, relatively high volume type. As explained in this document, with such a relatively large microwave chamber, the operation of the apparatus at atmospheric pressure (which is desirable) whilst maintaining a plasma therein is not straightforward. A partial solution is proposed by the arrangement of WO-A-96/02934, in which the struck plasma is contained within a confinement vessel in the apparatus and the microwave power to the vessel is then controlled. Nevertheless, this arrangement does still suffer from potential instability of the plasma, particularly at low flow rates. This instability may cause the plasma to stick to one side of the reaction tube. In the case of silica glass, if the plasma touches the glass even for a few seconds, it may result in the glass melting and the destruction of the system.

A further problem which has been encountered is that, after the plasma has been generated, the plasma itself may ‘stick’ to the container walls, causing the latter to increase in temperature. This increase may cause the absorption of microwaves by the container walls, resulting in a loss of plasma maintenance.

The object of the present invention is to provide a stable plasma, generated at atmospheric pressure, and suitable for processing relatively high volumes of plasma and sample materials.

According to a first aspect of the present invention, there is provided a microwave plasma apparatus comprising: a microwave chamber for containing gas and a plasma once initiated, the chamber having an inlet and an outlet; means for radiating microwave energy into said chamber to produce a plasma therein, the microwave chamber and the means for radiating microwave energy being adapted so as to establish a non-resonant, multimode microwave cavity; means for initiating said plasma; and a fluid inlet member upstream of the microwave chamber inlet and in fluid communication therewith, the fluid inlet member being adapted to alter the direction of flow of a received supply of gas so as to introduce the gas into the microwave chamber via the inlet thereof as a vorticular or swirled flow.

The use of a non-resonant, multimode cavity results in a relatively “untuned” device which in turn allows the plasma to adapt readily to changes in process conditions and vessel shapes. The use of a fluid inlet member which introduces vorticular or swirled flow to a gas which will establish the plasma provides a significantly more energy-efficient stable and controllable microwave plasma apparatus. Moreover, the position of the plasma is better constrained. The flow rate can likewise be increased; plasma gas flow rates of up to 200 litres/minute can be employed although, typically, rates of 10 to 20 litres/minute and no more than 40 litres/minute are currently preferred. Indeed, a further advantage of the arrangement of the present invention is that it permits stable and controllable low flow rates to be sustained.

In preference, the cavity is relatively large; for example the cavity length may be of the same order as the wavelength of the microwaves.

Whilst the apparatus is particularly suitable for operation at atmospheric pressure, it is possible to operate it at lower or higher pressures for certain applications.

Preferably, the fluid inlet member comprises one or more conduits arranged to receive the supply of gas, and a curved section passage in communication with the microwave chamber inlet, the or each conduit having a longitudinal axis which is substantially tangential to a radial axis of the said curved section passage. The gas thus flows in through the conduits and is wrapped around the walls of the curved section passage to create the vorticular flow.

Preferably, the or each conduit causes the gas to flow in a generally downward direction into the curved section passage. The longitudinal axis of the or each conduit preferably meets the longitudinal axis of the curved section passage at an angle between about 90° and about 120°, and preferably at 105°. Thus the conduits force the gas into the curved section passage (which preferably forms a part of the microwave chamber), and from there into the main body of the microwave chamber, in a generally downward direction.

Of course, by “downward”, it is simply meant that the gas flows towards the exit. In the typical arrangement, this is vertically below the inlet, but it is to be understood that the device may be operated at any arbitrary orientation. Thus, the chamber may for example be mounted upside down, or horizontally, so that the inlet is then, strictly, above the exit or horizontally in line with it, respectively. The word “downward” is thus to be understood in this context.

Preferably, the microwave chamber further includes a vessel arranged to confine the plasma within a volume which is less than the total volume of the said microwave chamber. In that case, the curved section passage and the vessel may each be substantially right-cylindrical. The curved section passage is preferably substantially coaxial with the vessel and chamber inlet, with the curved section passage and the inlet each being slightly larger in diameter than the diameter of the vessel. The vessel may be formed of a refractory material such as quartz. Preferably, the microwave chamber outlet is defined by a nozzle adapted to cause plasma gas to exit therethrough as a jet. In the alternative, the chamber outlet may not be throttled and a full diameter outlet may instead be desirable, for example for high flow VOC treatment and/or to increase the area of coverage.

In an alternative embodiment, the vessel may have a waist portion so as to form an ‘egg-timer’ shape. This shape is particularly beneficial at low flow rate as it acts to prevent vessel overheating.

The apparatus may further comprise a mixing chamber located downstream of the microwave chamber and in fluid communication therewith, the mixing chamber being arranged to receive plasma gas from the microwave chamber via the outlet thereof. The mixing chamber may then further comprise a reactant inlet for introduction of reactant material into the said mixing chamber.

The generally downward and spiral or vorticular flow of plasma gas into the mixing chamber is advantageous in that it prevents back flow of reactant material up the microwave chamber. Instead, any reactant material is forced in a generally downward direction by the flow of the plasma gas.

The means for radiating the microwave energy into the chamber is preferably a variable power magnetron capable of generating up to 5 kW of power (although other magnetrons capable of generating higher power outputs may be employed in certain cases). The volume in which the plasma is generated is typically around 800 cm³, although larger and smaller volumes are possible. The preferred frequency is 2.45 MHz but the apparatus may also be operated at, for example, 896 MHz. In principle, other frequencies may be employed.

In accordance with a second aspect of the present invention, there is provided a method of generating a plasma in a microwave plasma apparatus comprising: introducing swirled or vorticular movement to a flow of gas; supplying the said vorticularly moving gas to a microwave chamber of the microwave plasma apparatus; and radiating microwave energy into the chamber so as to establish a non-resonant, multimode microwave cavity in which a plasma is produced.

Further advantageous features are set out in the claims appended hereto.

### BRIEF DESCRIPTION OF THE DRAWINGS

The invention may be put into practice in a number of ways, and one will now be described by way of example only and with reference to the following drawings, in which:

FIG. 1 shows, schematically, a side-sectional view of a microwave plasma apparatus in accordance with an embodiment of the invention; and

FIG. 2 shows a plan view of the upper part of the microwave plasma apparatus of FIG. 1.

### DETAILED DESCRIPTION

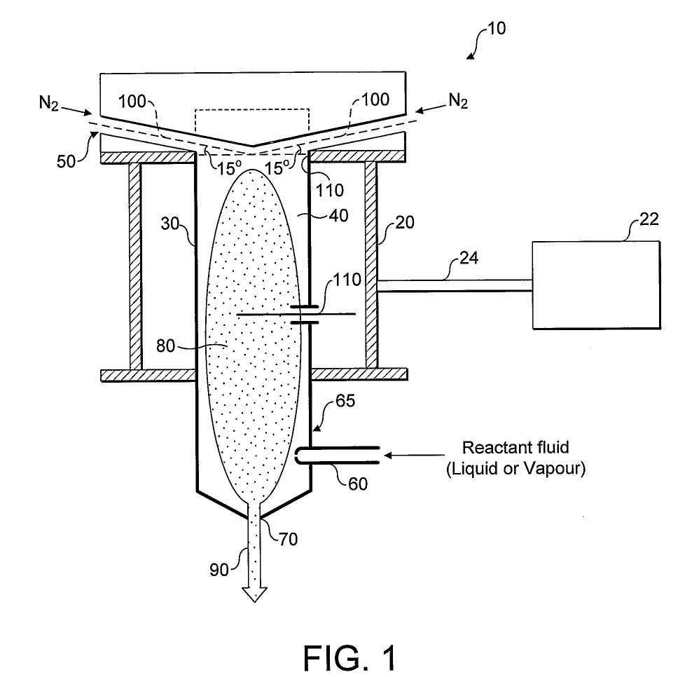

Referring first to FIG. 1, a plasma generating apparatus 10 is shown. The apparatus 10 includes a microwave cavity 20 which is coupled to a microwave source 22 by a wave guide 24. The microwave source is, in preference capable of producing a range of power outputs and frequencies up to 5 kW and 2.45 Ghz respectively; although typically the maximum available frequency (2.45 Ghz) is preferred, lower frequencies (such as 896 MHz) may be used instead. Moreover, whilst a continuous microwave source is described in the following, it is to be understood that a pulsed source is equally feasible.

Within the microwave cavity 20 is a reaction tube 30 which defines a plasma cavity 40. The reaction tube 30 is preferably formed from a refractory material such as quartz. At the upper end of the reaction tube 30, as seen in FIG. 1, a gas inlet member 50 is provided. The preferred configuration of this manifold, and its purpose, will be described in further detail below.

Although, in FIG. 1 it will be seen that the reaction tube 30 is in preference right cylindrical, it will be understood that other shapes are contemplated. For example, a wasted “egg-timer” shape may be suitable for some applications.

The reaction tube 30 opens into a mixing zone 65 which is beneath the microwave cavity 20. A feedstock injection port 60 opens into the mixing zone 65 and allows injection of a reactant fluid in liquid or vapour form. It is, however, to be understood that the reactant fluid can be supplied instead further up the reaction tube 30 and indeed as a mixture along with the plasma gas via the gas inlet member 50.

The mixing zone 65 has an opening opposite the input to the mixing zone from the microwave cavity 20, which is defined by an exit nozzle 70. The system is electrodeless and a plasma is initiated with a graphite rod 110 within the microwave chamber 20. Once the plasma has been struck, the graphite rod 110 is withdrawn as it is not required to maintain the plasma, which is sustained by the collision of electrons which have been accelerated by the microwave field with the other (larger) species present (and with each other), leading to raised temperatures. The diffuse, glowing plasma 80 is homogeneous and its shape can be changed according to the reaction tube 30. The volume of the plasma (which is determined by a number of factors including flow nozzle size, plasma chamber size and shape, and gas type) can be controlled by adjustment of the input power.

Although the microwave cavity 20 and mixing zone 65 have been described as separate components, it will be understood (and may be seen even from the schematic diagram of FIG. 1) that the mixing zone 65 is in fact a smooth, continuous extension to the microwave cavity 20, and that microwaves will in fact be present in the mixing zone 65 as well.

A range of dimensions may be employed for the apparatus 10. However, in preference, the reaction tube 30 has a diameter of around 8 cm. The diameter of the microwave chamber 20 is preferably around 16 cm, and the chamber 20 is also around 16 cm in length. The mixing zone 65 is around 10 cm in length but can be shorter or significantly longer, to permit advantageous variations in processing conditions.

Coupled with the variable 5 kW microwave source, the microwave cavity 20 acts as a multimode microwave cavity. This is preferable to a tuned cavity or waveguide which does not produce a uniform field. Moreover, the microwave cavity 20 provides a more diffuse, less intense plasma. This provides a more chemically rich mix of activating species, makes it more manageable, and provides a larger volume. The plasma extinguish time in the cavity 20 is less than 10 ms.

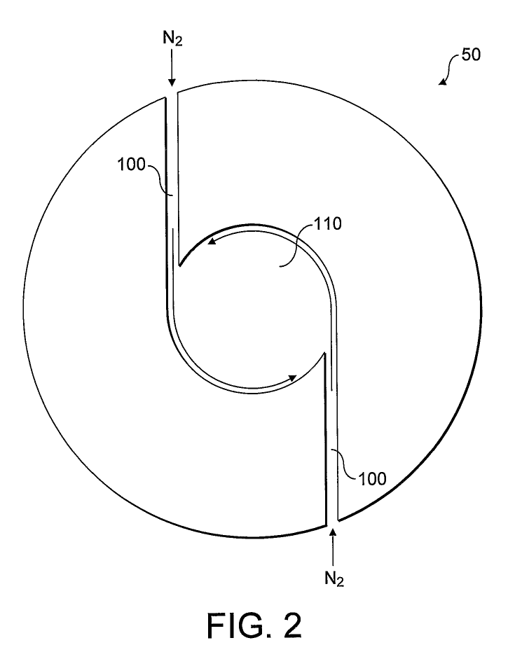

In operation, a small amount of plasma-forming gas (in the described embodiment, this is typically nitrogen or argon) is introduced into the reaction tube 30 via the gas inlet member 50. This gas inlet member 50 is shown in plan view in FIG. 2 and contains a central, generally cylindrical bore 110. As seen from FIG. 1, this cylindrical bore 110 is coaxial with the longitudinal bore of the reaction tube 30, the mixing zone 65 and the nozzle 70. In preference, the diameter of the central bore 110 of the gas inlet member 50 is slightly larger than the diameter, of the reaction tube 30 and the mixing zone 65.

In the illustrated embodiment of FIG. 2, plasma gas is supplied to the reaction tube 30 and the microwave cavity 20 by two opposed gas inlets 100. These gas inlets open into the central bore 110 of the gas inlet member 50 at a tangent as best seen in FIG. 2. The longitudinal axes of the gas inlets 100 are also canted downwards at an angle of around 105° to the longitudinal axis of the microwave cavity 20 and reaction tube 30 in particular. Because the plasma gas is fed into the central bore 110 tangentially, it is wrapped around in a generally circular direction so that the gas as injected into the reaction tube 30 is likewise swirling around. The downward cant of the inlets 100 introduces a downward component to the flow of the plasma gas so that the resultant gas flow into the microwave cavity is in the form of a vortex.

This vorticular flow of plasma gas prevents the silica reaction tube 30 from overheating, particularly at low flow rates; overheating leads to the reaction tube 30 becoming absorbent to microwave energy which in turn leads to thermal runaway. It will be understood from the foregoing, however, that the vorticular flow provides an additional advantage of stability which permits relatively high flow rates.

In operation, a small amount of plasma-forming gas is first of all introduced into the reaction tube 30 via the gas inlet member 50. The microwave source 22 is then activated and a graphite lighting rod 110 temporarily inserted through the aperture located midway along the length of the reaction tube, as seen in FIG. 1. The flow rate of the nitrogen plasma gas is then typically increased, and a body of plasma 80 is established which, at its broadest point, fills the reaction tube 30. Other methods of starting the plasma could of course be contemplated. Such as, but not limited to, employing a reduced pressure (around 30 mbar), at which pressure spontaneous ignition occurs, or using a pair of electrodes energised by a Tesla coil.

A plasma “jet” 90 extrudes through the exit nozzle 70 of the mixing zone 65. The nozzle 70 usually has a restricted outlet which increases the speed of the jet 90, although it is also possible or the outlet to be as wide as the full diameter of the reaction tube. This in turn reduces the dwell time in the gas phase of the activated species from the reactant fluid injected via the feedstock injection port 60.

The arrangement of FIGS. 1 and 2 permits relatively high plasma gas flow rates. Depending upon the inlet swirl and outlet, flow rates of up to 5000, litres per minute may be provided. Current applications (such as surface treatment and powder production), however, typically employ a flow rate of 40 litres/minute although higher rates are preferred for volatile organic compound (VOC) treatment. The stability, size and shape of the body of plasma 80, as well as the dimensions of the plasma jet 90, (all of which are a result of a variety of factors as explained above) are controlled by the power of the microwave source 22 and the flow rate of the plasma gas.

As to reactant fluids, typical flow rates of between about 0.5 litre/minute and 2 litres/minute have been found to be appropriate for injection of a liquid reactant, and here a suitable reservoir such as, for example, a Drechsel bottle is employed. The gaseous reactant fluids, by contrast, flow rates up to 3 litres/minute have been found particularly suitable with a flow rate controlled by a mass flow controller. During operation, a considerable amount of heat is generated and a degree of cooling may optionally be provided by an enclosed aluminium water jacket (not shown in the Figures). Solid state deposits from the apparatus 10 can be collected either from around the nozzle 70, or alternatively downstream of the nozzle 70. In that case, either a filter arrangement can be employed to collect solid phase material downstream of the nozzle 70, or the jet 90 can be directed toward a substrate for deposition of solid phase materials onto that.

In yet a further alternative, a further processing chamber (not shown) may be provided downstream of the nozzle 70 as well. This allows control of the environment around the jet. The conditions in this further processing chamber also (in part) help to determine the plasma volume. Conditions within this further processing chamber can also be controlled: for example, it may be at a reduced pressure relative to the mixing zone 65, it might be supplied in the other gas types (e.g. helium), it may be injected with feedstock materials or may receive a further microwave or rf energy input.

The plasma flow out of the apparatus may also be manipulated: for example, in VOC work, it is possible to split off a stream from the incoming gas flow, divert it around the plasma, and then mix it with the emerging plasma jet in this further processing chamber below the nozzle 70.

One specific example of the use of the apparatus described above will now be provided.

### EXAMPLE

### Production of Carbon Black

The apparatus of FIGS. 1 and 2 has been found to be particularly suitable for the production of carbon black. Carbon black is a well-known substance formed of spheroidally-shaped particles grouped together into chains or clusters known as aggregates. Carbon black is formed by the dissociation of hydrocarbons and finds use as a filler for rubber products, in the manufacture of printing inks, tinting, and in paper and fibre colourings. Traditional methods for the production of carbon black (such as lamp black, furnace black and gas black) relied upon partial combustion of petrochemical and coal tar oils. Over recent decades, however, plasma systems have also been employed as they are typically more efficient and environmentally friendly. It is furthermore known that carbon blacks generated by a plasma process can have unique properties and characteristics. The apparatus of FIGS. 1 and 2, however, allows the production of carbon blacks having much more tightly controlled particle diameters than previously.

As set out in Table 1 below, nitrogen was employed as a plasma gas with microwave source 22 generating a power output of 2.77 kW. Various flow rates of plasma gas were employed, for two different reactant materials or feedstocks at a variety of different flow rates. Samples were collected from the nozzle 70, from within the jet 90, and downstream of the nozzle 70 using a bag filter.

TABLE 1

| APNEP Conditions | | | | | | | | | |
|---|---|---|---|---|---|---|---|---|---|
| | | | | | Feedstock | | | | |
| | | | Flow | | Flow | | Elemental Analysis | | |
| | Power | Plasma | Rate | | Rate | Sample | C | H | N |
| Ref | (kW) | Gas | (l/min) | Feedstock | (l/min) | Collection | (%) | (%) | (%) |
| A | 2.77 | N2 | 40 | Propane | 0.9 | Nozzle | 98.8 | <0.1 | <0.1 |
| B | 2.77 | N2 | 40 | Propane | 0.5 | Nozzle | 98.1 | <0.1 | <0.1 |
| C | 2.77 | N2 | 40 | Propane | 0.9 | Jet | 98.5 | <0.1 | <0.1 |
| D | 2.77 | N2 | 40 | Toluene | 2.0 | Bag filter | 97.9 | <0.1 | <0.1 |
| E | 3.68 | N2 | 24 | Toluene | 2.0 | Nozzle | 98.8 | <0.1 | <0.1 |
| F | 2.77 | N2 | 24 | Toluene | 2.0 | Nozzle | 99.1 | <0.1 | 0.2 |
| G | 2.77 | N2 | 28 | Toluene | 2.0 | Bag Filter | 99.8 | <0.1 | 0.2 |
| H | 2.77 | N2 | 24 | Toluene | 2.0 | Bag Filter | 97.9 | <0.1 | <0.1 |
| I | 2.77 | N2 | 24 | Toluene | 2.5 | Bag Filter | 98.6 | <0.1 | <0.1 |
| J | 2.77 | N2 | 40 | Toluene | 2.5 | Bag filter | 98.6 | <0.1 | <0.1 |

In each case, the resultant particles were subjected to microanalysis and, in each case, were found to contain almost all carbon. Transmission electron microscopy (TEM) images were acquired of the carbon material prepared using the propane reactant, as set out in Table 2. Particle diameters were measured directly off the electron micrograph where it was possible to discern individual particles. The carbon material has a clear “grape-like” structure with a high degree of aggregate structure. Additionally, the majority of the particles within an aggregate are joined together, deforming their individual spherical shape into a fused chain of spheres. The narrow range of diameters of the particles is clearly seen from

TABLE 2

| | | | | Particle | |
|---|---|---|---|---|---|
| APNEP Conditions | | | | Dimensions | |
| | Nitrogen | Propane | | Mean | |
| Power | Flow Rate | Flow Rate | Sample | Diameter | Range |
| (kW) | (l/min) | (l/min) | Point | (nm) | (nm) |
| 2.77 | 40 | 0.9 | Nozzle | 36 | 34-40 |
| 2.77 | 40 | 0.9 | Jet | 36 | 34-38 |

Contact angle measurements were made of both propane (C₃H₈) and toluene (C₇H₈) derived carbon blacks and the results are set out in Tables 3 and 4 below. Specific surface area measurements using various techniques are also shown for propane and toluene derived carbon blacks, in Tables 5 and 6 respectively.

TABLE 3

| APNEP Conditions | | | | | | | |
|---|---|---|---|---|---|---|---|
| | Ni- | | | Contact Angle | | | |
| | trogen | Propane | | Measurements | | | |
| | Flow | Flow | Substrate | | Mean | | |
| Power | Rate | Rate | Distance | | angle | | σ |
| (kW) | (l/min) | (l/min) | (mm) | n | (°) | Range (°) | (°) |
| 2.77 | 40 | 1.0 | 40 | 10 | 142.4 | 136.25-151.00 | 5.2 |
| 2.77 | 40 | 1.0 | 70 | 8 | 139.6 | 134.50-146.25 | 4.0 |
| 3.68 | 30 | 1.0 | 40 | 10 | 147.2 | 129.00-152.50 | 6.6 |

TABLE 4

| APNEP Conditions | | | | | | | |
|---|---|---|---|---|---|---|---|
| | Ni- | | | Contact Angle | | | |
| | trogen | Propane | | Measurements | | | |
| | Flow | Flow | Substrate | | Mean | | |
| Power | Rate | Rate | Distance | | angle | | σ |
| (kW) | (l/min) | (l/min) | (mm) | n | (°) | Range (°) | (°) |
| 2.77 | 24 | 2.0 | 40 | 7 | 132.4 | 126.50-139.00 | 4.3 |
| 2.77 | 24 | 2.5 | 40 | 8 | 130.5 | 124.00-137.00 | 3.9 |
| 3.68 | 28 | 2.0 | 40 | 10 | 128.0 | 116.00-135.00 | 5.0 |

TABLE 5

| | | Specific Surface Area |
|---|---|---|
| Method | Data Set | (m²/g) |
| BET | Nitrogen Adsorption | 90.19 |
| BJH | Nitrogen Desorption | 82.81 |
| Porosimetry | Mercury | N/A |

TABLE 6

| | | Specific Surface Area |
|---|---|---|
| Method | Data Set | (m²/g) |
| BET | Nitrogen Adsorption | 117.13 |
| BJH | Nitrogen Desorption | 116.90 |
| Porosimetry | Mercury | 232.30 |

Although a preferred embodiment has been described, it is to be understood that this is by way of example only and that various modifications and improvements may be employed. For example, although FIG. 1 shows the apparatus with an exit nozzle 70 at the “bottom” of the reaction tube 30/mixing zone 65, it is possible to run the apparatus “upside down”, that is, with the exit nozzle 70 at the top of the apparatus instead. This arrangement, which requires cooling of the flange surrounding the nozzle, has been employed for the treatment of carbon fibres, using a “bell-jar”-shaped vessel having a domed top. A small tube extends vertically upwards from the domed top and the plasma extends upwards through that tube. The tube itself is connected to a second horizontal tube to form a ‘T’-junction and fibre passes along that horizontal tube where it is struck by the plasma at the confluence of the orthogonal tubes. Horizontal arrangements can also be employed.

The apparatus described above has many applications, such as cleaning and degreasing, destruction of VOCs, treatment of polymeric and carbon fibres, coating of glass, ceramics and polymers, surface modification of polymers, and production of powders. Modifications in the details of the apparatus may be appropriate, depending upon the specific application, but the underlying principles of plasma generation remain the same.

What is claimed is:

1. A microwave plasma apparatus comprising:
a microwave chamber for containing gas and a plasma once initiated, the chamber having an inlet and an outlet;
means for radiating microwave energy into said chamber to produce a plasma therein, the microwave chamber and the means for radiating microwave energy being adapted so as to establish a non-resonant, multimode microwave cavity; and
a fluid inlet member upstream of the microwave chamber inlet and in fluid communication therewith, the fluid inlet member being adapted to alter the direction of flow of a received supply of gas so as to introduce the gas into the microwave chamber via the inlet thereof as a vorticular or swirled flow.

2. The apparatus of claim 1, in which the fluid inlet member comprises one or more conduits arranged to receive a supply of gas, and a curved section passage in communication with the microwave chamber inlet, the or each conduit having a longitudinal axis which is substantially tangential to a radial axis of the said curved section passage.

3. The apparatus of claim 2, in which the said curved section passage has a longitudinal axis, the longitudinal axis of the or each conduit intersecting the longitudinal axis of the passage at angle between about 90° and about 120°.

4. The apparatus of claim 3, in which the longitudinal axes of the passage and the or each conduit intersect at 105°.

5. The apparatus of claim 2, in which the microwave chamber further includes a vessel arranged to confine the plasma within a volume which is less than the total volume of the said microwave chamber.

6. The, apparatus of claim 5, in which the vessel is substantially right cylindrical, and in which the curved section passage in the fluid inlet member is also substantially right cylindrical and substantially coaxial with the vessel and the chamber inlet.

7. The apparatus of claim 5, in which the vessel is formed of a refractory material such as quartz.

8. The apparatus of claim 1, in which the microwave chamber outlet is defined by a nozzle adapted to cause a plasma gas within the chamber to exit through the nozzle as a jet.

9. The apparatus of claim 1, further comprising a mixing chamber located downstream of the microwave chamber and in fluid communication therewith, the mixing chamber being arranged to receive a plasma gas from the microwave chamber via the outlet thereof, the mixing chamber further comprising a reactant inlet for introduction of reactant material into the said mixing chamber.

10. The apparatus of claim 9, wherein the mixing chamber has an exhaust port defined by a nozzle, the nozzle being shaped so as to cause the plasma gas and any reactant material mixed therewith to exit via the nozzle as a jet.

11. The apparatus of claim 1, in which the means for radiating the microwave energy into the chamber comprises a variable power magnetron capable of generating up to 5 kW of power.

12. The apparatus of claim 1, in which the plasma is generated in a volume of at least 250 cm³ and preferably around 800 cm³.

13. The apparatus of claim 1, further comprising means for generating a flow of the said gas which is arranged to generate a gas flow rate of at least 10 litres/minute and preferably up to 200 litres/minute, most preferably up to 5,000 litres/minute.

14. The apparatus of claim 1, wherein the microwave chamber is arranged to contain the gas at a pressure substantially at or above atmospheric pressure.

15. The apparatus of claim 1, further comprising means for initiating the plasma within the chamber.

16. A method of generating a plasma in a microwave plasma apparatus comprising:
introducing swirled or vorticular movement to a flow of gas; supplying the said vorticularly moving gas to a microwave chamber of the microwave plasma apparatus; and radiating microwave energy into the chamber so as to establish a non-resonant multimodal microwave cavity in which a plasma is produced.

17. The method of claim 16, in which the flow of gas is supplied to the chamber at a flow rate of at least 10 litres/minute, preferably up to 200 litres/minute, and most preferably up to 5,000 litres/minute.

18. The method of claim 16, in which the microwave energy is radiated at a power of at least 1 kW and preferably up to 5 kW.

19. The method of claim 16, further comprising supplying a reactant material to the plasma.

20. The method of claim 19, in which the step of supplying a reactant material to the plasma comprises supplying a hydrocarbon material thereto.

21. The method of claim 19, further comprising supplying the reactant material to a mixing chamber downstream of the microwave chamber for reaction with the plasma in the said mixing chamber.

22. The method of claim 16, further comprising containing the gas in the chamber substantially at or above atmospheric pressure.

23. The method of claim 16, further comprising initiating the plasma in the chamber.

24. A carbon black material whenever produced by a method as defined in claim 16.
